(19) United States
(12) Patent Application Publication
(10) Pub. No.: US 2005/0286582 A1
(43) Pub. Date: Dec. 29, 2005

(54) Photosemiconductor device

(75) Inventors: Akinori Hayakawa, Kawasaki (JP); Shinsuke Tanaka, Kawasaki (JP); Ken Morito, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/023,531

(22) Filed: Dec. 29, 2004

(30) Foreign Application Priority Data
Jun. 28, 2004 (JP) 2004-189406

(51) Int. Cl. H01S 5/00

(52) U.S. Cl. 372/44.01; 372/45.01

(57) ABSTRACT

In a TTG-DFB-LD including a MQW wavelength control layer 16 whose refractive index varies by the current injection, the effective forbidden bandwidth of the MQW wavelength control layer 16 is larger by a value in the range of above 40 meV including 40 meV and below 60 meV excluding 60 meV than an energy of light generated in the MQW active layer 20.

### CROSS-REFERENCE TO RELATED APPLICATIONS

This application is based upon and claims priority of Japanese Patent Application No. 2004-189406, filed on Jun. 28, 2004, the contents being incorporated herein by reference.

### BACKGROUND OF THE INVENTION

The present invention relates to a photosemiconductor device, more specifically, a photosemiconductor device including a refractive index control layer whose refractive index is changed by current injection.

In the optical communication system, in order to meet the increasing data traffic, WDM (Wavelength Division Multiplexing) mode was developed and is practically used. The WDM system is for transmitting optical signals of a plurality of wavelengths at once by one optical fiber.

Furthermore, in the optical communication system using WDM mode in the future, high-level processing, such as OADM (Optical Add Drop Multiplexer), wavelength routing, optical packet transmission, etc., is proposed so as to form flexible systems of large capacities by more positively using the wavelength information of optical signals. In order to realize such high-level processing, the light sources used in the optical communication system are required to have high-speed wavelength variability, wide wavelength variable ranges and stable wavelength controllability.

As the light source for such optical communication system of WDM mode, applications of various wavelength variable lasers have been proposed. Among them, TTG-DFB-LD (Tunable Twin Guide Distributed FeedBack Laser Diode) attracts a great deal of attention (refer to, e.g., Specification of U.S. Pat. No. 5,048,049).

The TTG-DFB-LD has advantages that the oscillation wavelength can be continuously controlled by a single mode, and the wavelength control is speedy. Furthermore, the TTG-DFB-LD has the advantage that the mechanism for the wavelength control is simple. Because of these advantages, the TTG-DFB-LD is prospectively applicable to the light source for the optical communication system of the WDM mode, etc.

The structure of the TTG-DFB-LD will be explained with reference to FIG. 11. FIG. 11 is a sectional view of the TTG-DFB-LD, which illustrates the structure.

On a p type InP semiconductor substrate 100, a p type InGaAsP diffraction grating layer 102 with a diffraction grating formed on, a p type InP spacer layer 104, an InGaAsP wavelength control layer 106, an n type InP intermediate layer 108, an InGaAsP active layer 110 and a p type InP clad layer 112 are formed sequentially the latter of the former, and these layers and an upper part of the semiconductor substrate 100 are etched in a mesa stripe.

On the semiconductor substrate 100 on both sides of the mesa stripe, a burying layer 114 of an n type InP layer, p type InP layer and an n type InP layer formed sequentially one on another, burying the mesa stripe.

On the buried layer 114 and the clad layer 112 of the mesa stripe, a p type InP cap layer 116 is formed. On the cap layer 116, a p type electrode 118 is formed, electrically connected to an active layer 110 via the cap layer 116 and the clad layer 112.

On the burying layer 114, an n type electrode 120 is formed, electrically connected to the intermediate layer 108 via the burying layer 114.

On the underside of the semiconductor substrate 100, a p type electrode 122 is formed, electrically connected to the wavelength control layer 106 via the semiconductor substrate 100, the diffraction grating layer 102 and the spacer layer 104.

In the TTG-DFB-LD having the above-described structure, a prescribed voltage is applied between the p type electrode 118 and the n type electrode 120 to inject current from the p type electrode 118. The current injected from the p type electrode 118 is injected into the active layer 110 via the cap layer 116 and the clad layer 112 to be led out from the n type electrode 120 via the intermediate layer 108 and the burying layer 114. Current of above an oscillation threshold is injected into the active layer, whereby light generated in the active layer 110 is caused to oscillate in the DFB mode by the diffraction grating formed in the diffraction grating layer 102.

Concurrently, a prescribed voltage is applied between the p type electrode 122 and the n type electrode 120 to inject current from the p type electrode 122. The current injected from the p type electrode 122 is injected into the wavelength control layer 106 via the semiconductor substrate 100, the diffraction grating layer 102 and the spacer layer 104 to be led out from the n type electrode 120 via the intermediate layer 108 and the burying layer 114. The current is injected into the wavelength control layer 106, whereby a refractive index of the wavelength control layer 106 is changed by plasma effect, and a DFB oscillation wavelength is changed.

As described above, in the TTG-DFB-LD, the intermediate layer 108 makes the 2 functional layers, i.e., the active layer 110 and the wavelength control layer 106 electrically independent of each other. Accordingly, the current amount to be injected in the respective functional layers is controlled, whereby the control of the laser oscillation and the control of the oscillation wavelength can be made independently of each other.

As described, when the TTG-DFB-LD is formed of InP/InGaAsP-based materials, the active layer emits light at a 1.55 μm-band. In this case, generally, an about 1.3 μm-forbidden bandwidth is given to the wavelength control layer.

The background arts of the present invention are disclosed in e.g., Japanese published unexamined patent application No. Hei 06-104524 (1994), Japanese published unexamined patent application No. Hei 07-326820 (1995) and Japanese published unexamined patent application No. 2003-198055.

### SUMMARY OF THE INVENTION

In the variable wavelength lasers, such as the TTG-DFB-LD, etc., which controls the oscillation wavelength by changing the refractive index of the wavelength control layer by current injection, in order to increase the variable width of the oscillation wavelength, the following methods are considered. The method of increasing current injected into the wavelength control layer to thereby increase the change of the refractive index of the wavelength control layer is considered. The method of forming the wavelength control layer thick to thereby increase the light confinement in the wavelength control layer is also considered.

However, in the former method, the absorption of the wavelength control layer is increased with the current injection into the wavelength control layer, which raises the oscillation threshold, and also the output power of the laser beams is dropped. In the latter method, the fundamental absorption of the wavelength control layer becomes large, which also raises the oscillation threshold, and also lower the output power of the laser beams. Such oscillation threshold increase and the output power decrease of the laser beams are one of the causes for restricting the maximum variable width of the oscillation wavelength.

In order to make the variable width of the oscillation wavelength large without the oscillation threshold increase and output power decrease of the laser beams, it is essential to realize as the wavelength control layer a refractive index control layer having small fundamental absorption and large refractive index changes by the current injection.

To realize a refractive index control layer having small fundamental absorption and large refractive index changes by current injection is a problem not only with the TTG-DFB-LD, but also commonly with photosemiconductor devices including a refractive index control layer whose refractive index is changed by current injection, such as variable wavelength lasers, e.g. SG-DBR (Sampled-Grating Distributed Bragg Reflector) laser, SSG-DBR (Super-Structure-Grating Distributed Bragg Reflector) laser, and variable wavelength filters.

An object of the present invention is to provide a photosemiconductor device including a refractive index control layer having small fundamental absorption and large refractive index changes by current injection.

According to one aspect of the present invention, there is provided a photosemiconductor device comprising an optical waveguide including a refractive index control layer whose refractive index varies by current injection, an effective forbidden bandwidth of the refractive index control layer being larger by a value of above 40 meV including 40 meV and below 60 meV excluding 60 meV than an energy of light propagating through the optical waveguide.

According to another aspect of the present invention, there is provided a wavelength control method for light propagating a optical waveguide comprising a refractive index control layer having an effective forbidden bandwidth which is larger by a value of above 40 meV including 40 meV and below 60 meV excluding 60 meV than the light propagating through the optical waveguide, the method injecting current into the refractive index control layer to control a wavelength of the light propagating through the optical waveguide.

According to the present invention, in the photosemiconductor device comprising the optical waveguide including the refractive index control layer whose refractive index changes by current injection, the effective forbidden bandwidth of the refractive index control layer is made larger by a value of above 40 meV including 40 meV and below 60 meV excluding 60 meV than an energy of light propagating through the optical waveguide, whereby the fundamental absorption of the refractive index control layer can be made small, and the refractive index change of the refractive index control layer by the current injection can be made large. Thus, the present invention can realize the photosemiconductor devices having excellent device characteristics, such as variable wavelength lasers, variable wavelength filters, etc. having wide variable wavelength widths.

### BRIEF DESCRIPTION OF THE DRAWINGS

FIG. 1 is a graph of the dependency of the refractive index change of the refractive index control layer on the effective forbidden bandwidth of the refractive index control layer.

FIG. 2 is a graph of the dependency of the fundamental absorption of the refractive index control layer on the effective forbidden bandwidth of the refractive control layer.

FIGS. 3A and 3B are sectional views of the photosemiconductor device according to one embodiment of the present invention, which illustrate a structure thereof.

FIG. 4 is a graph of the wavelength variation characteristics of the photosemiconductor device according to the embodiment of the present invention.

FIGS. 5A-5C are sectional views of the photosemiconductor device according to the embodiment of the present invention in the step of the method for fabricating the photosemiconductor device, which illustrate the method (Part 1).

FIGS. 6A-6C are sectional views of the photosemiconductor device according to the embodiment of the present invention in the step of the method for fabricating the photosemiconductor device, which illustrate the method (Part 2).

FIGS. 7A-7C are sectional views of the photosemiconductor device according to the embodiment of the present invention in the step of the method for fabricating the photosemiconductor device, which illustrate the method (Part 3).

FIGS. 8A-8C are sectional views of the photosemiconductor device according to the embodiment of the present invention in the step of the method for fabricating the photosemiconductor device, which illustrate the method (Part 4).

FIGS. 9A-9C are sectional views of the photosemiconductor device according to the embodiment of the present invention in the step of the method for fabricating the photosemiconductor device, which illustrate the method (Part 5).

FIG. 10 is a graph of the result evaluating the photosemiconductor device according to the embodiment of the present invention.

FIG. 11 is a sectional view of the TTG-DFB-LD, which illustrates the structure thereof.

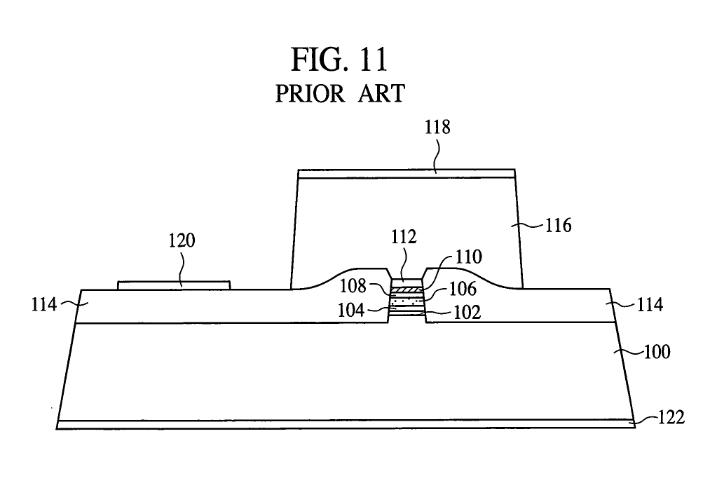

### DETAILED DESCRIPTION OF THE INVENTION

### Principle of the Present Invention

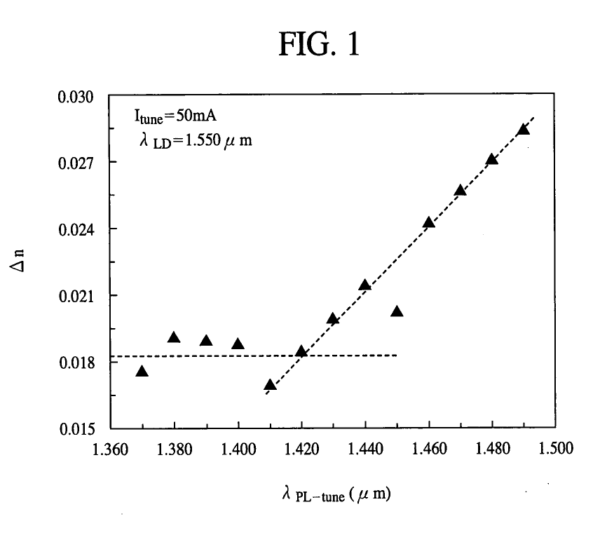

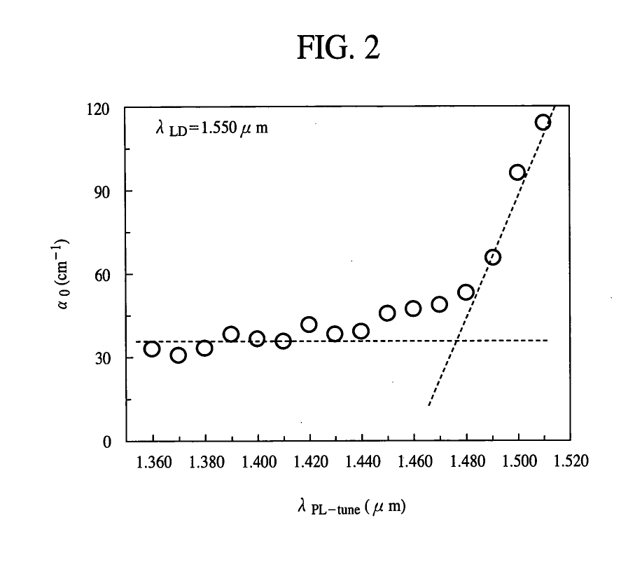

First, the principle of the present invention will be explained with reference to FIGS. 1 and 2. FIG. 1 is a graph of the dependency of the refractive index change An of the refractive index control layer on the effective forbidden bandwidth of the refractive index control layer. FIG. 2 is a graph of the dependency of the fundamental absorption α₀ of the refractive index control layer on the effective forbidden band of the refractive index control layer.

The inventors of the present application have made earnest studies of the refractive index control layer having the refractive index changed by current injection, which is used as the wavelength control layers, etc. of the variable wavelength lasers, such as TTG-DFB-LD, etc. so as to realize a refractive index control layer having a small fundamental absorption with respect to light-to-be-controlled which propagates through an optical waveguide including the refractive index control layer and has the wavelength, etc. to be controlled but having large refractive index changes. Resultantly, to realize such a refractive index control layer, they have noted the dependency of the refractive index change and the fundamental absorption of the refractive index control layer on the effective forbidden bandwidth of the refractive index control layer.

FIGS. 1 and 2 are graphs of the respective dependency of the refractive index change Δn and the fundamental absorption α₀ of the refractive index control layer on the effective forbidden bandwidth of the refractive index control layer, computed based on the experimental results. The wavelength of the light-to-be-controlled which propagates through the refractive index control layer and has the wavelength, etc. to be controlled by the refractive index control layer is a 1.55 μm-band here. The current Iₜᵤₙₑ to be injected into the refractive index control layer is 50 mA. The effective forbidden bandwidth of the refractive index control layer is converted into wavelength to be indicated by λ_{PL (PhotoLuminescence)-tune}.

As evident in the graph of FIG. 1, when λ_{PL-tune} is below 1.440 μm including 1.440 μm, An does not largely change even with the changes of λ_{PL-tune}. The dependency of Δn on λ_{PL-tune} is small. However, when λ_{PL-tune} is above 1.440 μm, An increases, depending on λ_{PL-tune}.

On the other hand, as evident in the graph of FIG. 2, in the region where λ_{PL-tune} is in the short wavelength region near 1.40 μm, α₀ gently increases as λ_{PL-tune} increases, i.e., becomes longer wavelength. λ_{PL-tune} further increase, and in the region where λ_{PL-tune} is near 1.475 μm, α₀ abruptly increases as λ_{PL-tune} increases.

The use of the refractive index control layer having the fundamental absorption α₀ increased as a variable wavelength control layer or a phase control layer is a cause for the increase of the internal loss of the laser oscillator, and the oscillation threshold of the laser is abruptly increased.

When the above-described characteristics of the dependency of the refractive index change Δn and the fundamental absorption α₀ of the refractive index control layer on the effective forbidden bandwidth λ_{PL-tune} of the refractive index control layer are considered, a value of the effective forbidden bandwidth λ_{PL-tune} of the refractive index control layer, which makes the fundamental absorption α₀ small and the refractive index change Δn large can be defined. Specifically, the effective forbidden bandwidth λ_{PL-tune} is set shorter by a value in the range from 0.075 μm including 0.075 μm to 0.11 μm excluding 0.11 μm than the wavelength 1.55 μm of the light-to-be-controlled. That is, when converted into energy, the effective forbidden bandwidth λ_{PL-tune} is set larger by a value in the range of 40 meV including 40 meV to 60 meV excluding 60 meV than the energy of the light-to-be-controlled. The effective forbidden bandwidth λ_{PL-tune} of the refractive index control layer is thus set, whereby a refractive index control layer having a small fundamental absorption α₀ with respect to the light-to-be-controlled and a large refractive index change Δn can be realized. A refractive index control layer having a small fundamental absorption α₀ and a larger refractive index change Δn is used as the wavelength control layer of a variable wavelength laser, such as the TTG-DFB-LD, etc., whereby the variable width of the oscillation wavelength can be made large without the increase of the oscillation threshold and the decrease of the output power of the laser beams.

The range of the value which makes the effective forbidden bandwidth λ_{PL-tune} of the refractive index control layer larger than the energy of the light-to-be-controlled can be arbitrarily set in the range of 40 meV including 40 meV to 60 meV excluding 60 meV. For example, the effective forbidden bandwidth λ_{PL-tune} can be set larger by a value of above 40 meV including 40 meV and below 55 meV including 55 meV than the energy of the light-to-be-controlled.

An embodiment in which a refractive index control layer which the present invention is applied to, is used as the wavelength control layer of a TTG-DFB-LD will be detailed below. The present invention is applicable not only to the wavelength control layer of the TTG-DFB-LD, but also to refractive index control layers of various photosemiconductor devices, whose refractive indexes are changed by current injection.

### One Embodiment of the Present Invention

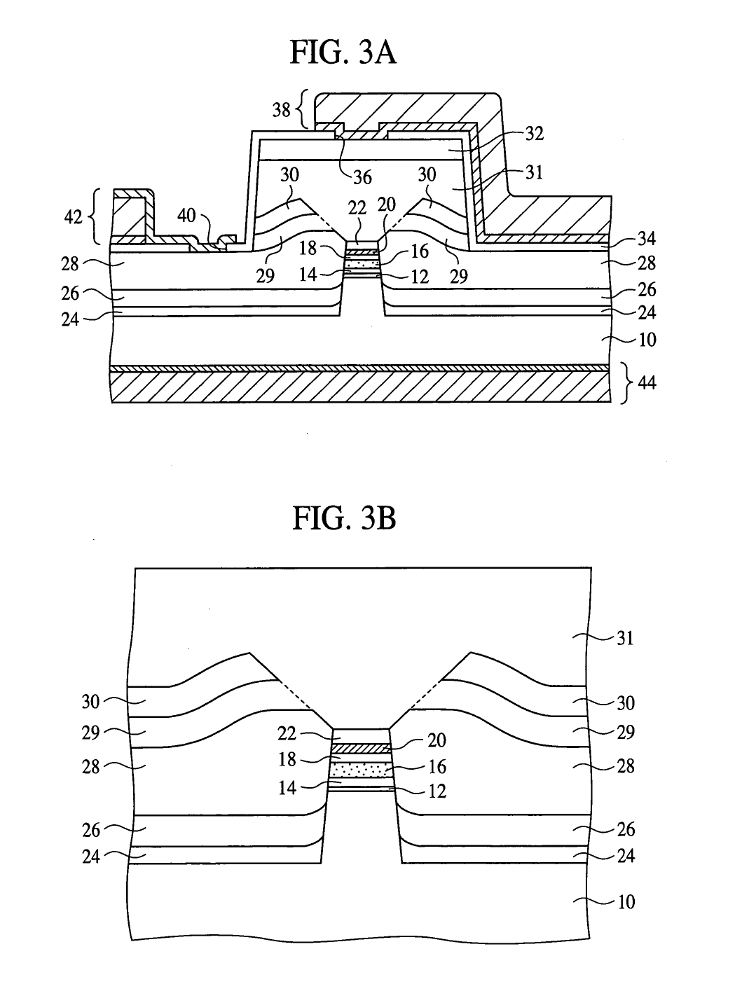

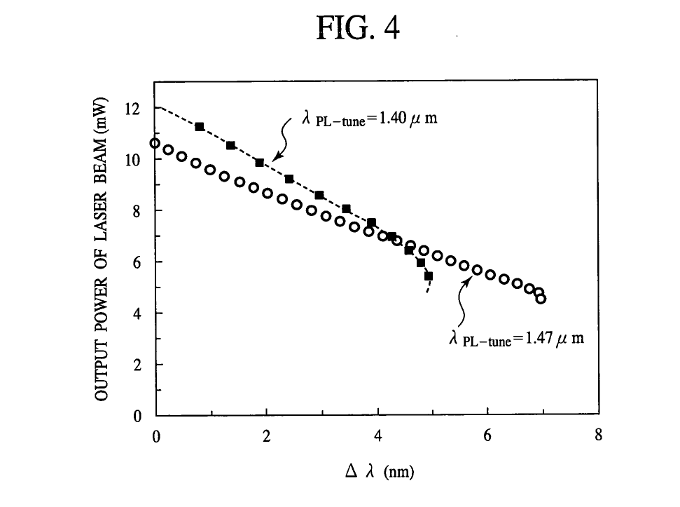

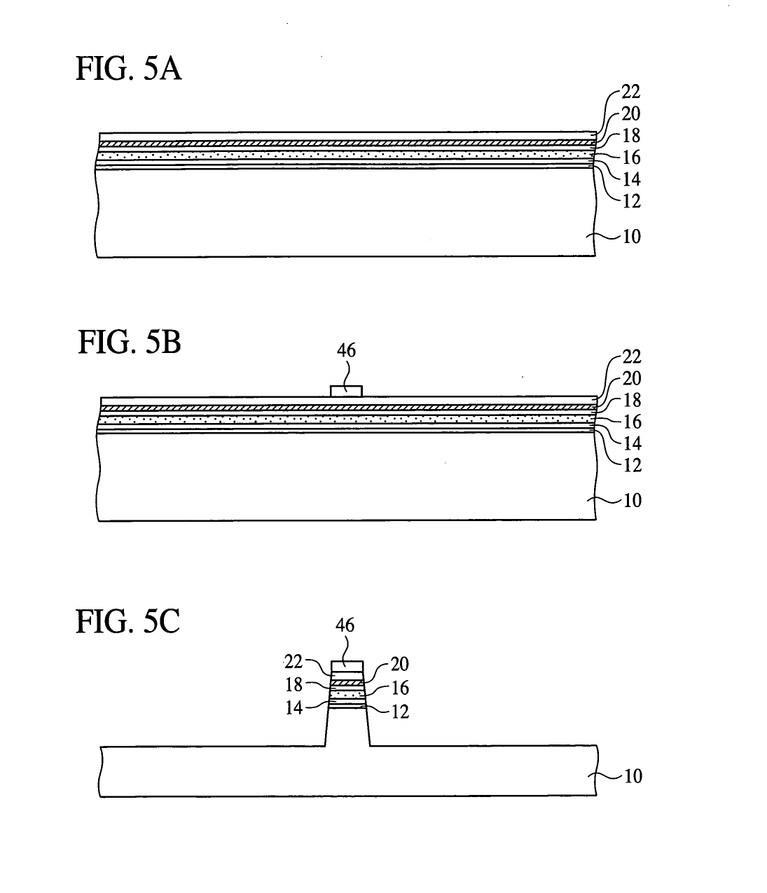

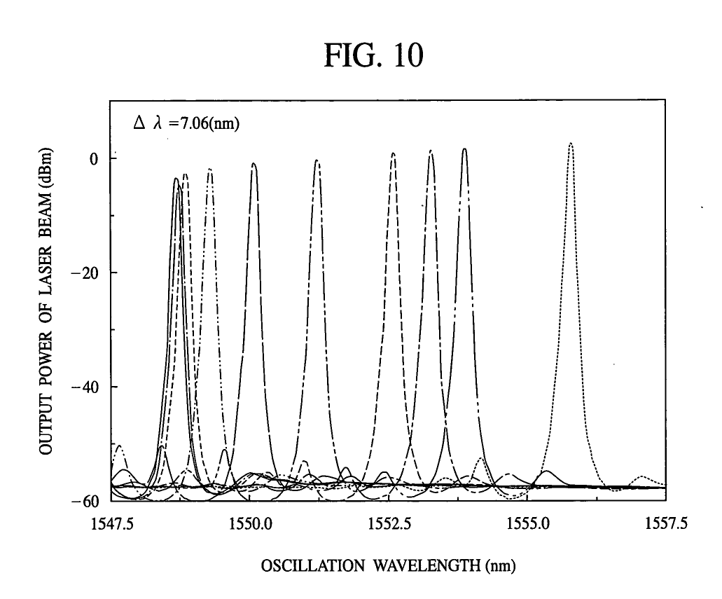

The photosemiconductor device according to one embodiment of the present invention will be explained with reference to FIGS. 3 to 10. FIGS. 3A and 3B are sectional views of the photosemiconductor device according to the present embodiment, which illustrate a structure thereof. FIG. 4 is a graph of wavelength variation characteristics of the photosemiconductor device according to the present embodiment. FIGS. 5A-5C to 9A-9C are sectional views of the photosemiconductor device according to the present embodiment in the steps of the method for fabricating the photosemiconductor device, which illustrate the method. FIG. 10 is a graph of the result evaluating the photosemiconductor device according to the present embodiment.

First, the structure of the photosemiconductor device according to the present embodiment will be explained with reference to FIGS. 3A and 3B. FIG. 3A is a sectional view of the photosemiconductor device according to the present embodiment, which illustrates the whole structure. FIG. 3B is an enlarged sectional view of the photosemiconductor device according to the present embodiment, which illustrates a layer structure of the mesa stripe portion.

The photosemiconductor device according to the present embodiment is TTG-DFB-LD which oscillates at, e.g., a 1.55 μm wavelength band.

On a semiconductor substrate 10 of p type InP there are formed a p type InGaAsP diffraction grating layer 12 of, e.g., a 0.07 μm-thickness and a 1.2 μm-λ_{PL} (PL peak wavelength), a p type InP spacer layer 14 of, e.g., a 0.1 μm-thickness, a MQW wavelength control layer 16 of, e.g., a 1.47 μm-λ_{PL}, an n type InP intermediate layer 18 of, e.g., a 0.2 μm-thickness, a MQW active layer 20 of, e.g., a 1.55 μm-λ_{PL}, an InGaAsP SCH (Separate Confinement Heterostructure) layer (not illustrated) of, e.g., a 0.02 μm-thickness and a 1.15 μm-λ_{PL} and a p type InP clad layer 22 of, e.g., a 0.2 μm-thickness are formed sequentially the latter on the former. These layers and an upper part of the semiconductor substrate are etched in a mesa stripe. The width of the mesa stripe is, e.g., 1.3 μm. The height of the mesa stripe is, e.g., 2.5 μm. In the diffraction grating layer 12, a diffraction grating of, e.g., an about 240 nm-period is formed. A p type InP buffer layer may be formed between the semiconductor substrate 10 and the diffraction grating layer 12.

The MQW wavelength control layer 16 has a multiple quantum well structure and is formed of an InGaAsP barrier layer of, e.g., a 10 nm-thickness and a InGaAsP well layer of, e.g., a 3 nm-thickness laid one on the other by, e.g., 15 periods. The effective forbidden bandwidth of the MQW wavelength control layer 16 is, e.g., 1.47 μm when converted into wavelength. That is, the effective forbidden bandwidth of the MQW wavelength control layer 16 is larger by, e.g., 43.5 meV than an energy of light of, e.g., a 1.55 μm-wavelength to be wavelength controlled by the MQW wavelength control layer 16. Thus, the effective forbidden bandwidth of the MQW wavelength control layer 16 is larger by a value in the range of above 40 meV including 40 meV and below 60 meV excluding 60 meV than an energy of light-to-be-controlled which is to be wavelength controlled by the MQW wavelength control layer 16.

The MQW active layer 20 has a multiple quantum well structure and is formed of an InGaAsP barrier layer of, e.g., a 10 nm-thickness and an InGaAsP well layer of, e.g., a 3 nm-thickness laid one on the other by, e.g., 7 periods.

On the semiconductor substrate 10 on both sides of the mesa stripe, an n type InP buried layer 24 of, e.g., a 0.5 μm-thickness, a p type InP buried layer 26 of, e.g., a 1.0 μm-thickness, an n type InP buried layer 28 of, e.g., a 1.0 μm-thickness, a p type InP buried layer 29 of, e.g., a 0.8 μm-thickness and an n type InP buried layer 30 of, e.g., a 0.3 μm-thickness are sequentially formed. These layers bury the mesa stripe, covering the side walls of the mesa stripe. These buried layers 24, 26, 28, 29, 30 form a current confining structure, the buried layers 24, 26, 28 realizing the current confinement on the side of the MQW wavelength control layer 16, and the buried layers 29, 30 realizing the current confinement on the side of the MQW active layer 20. The n type InP buried layer 28 is electrically connected to the intermediate layer 18.

On the n type InP buried layer 30 and the clad layer 22 of the mesa stripe, a p type InP cap layer 31 of, e.g., a 2.5 μm-thickness is formed.

On the cap layer 31, a p type InGaAs contact layer of, e.g., a 0.5 μm-thickness is formed.

The contact layer 32, the cap layer 31, the n type InP buried layer 30 and the p type InP buried layer 29 are formed in a prescribed width on the region containing the mesa stripe having the MQW wavelength control layer 16, the intermediate layer 18 and the MQW active layer 20, and the n type InP buried layer 28 is exposed on both sides thereof.

A protection film 34 of silicon oxide film is formed on the n type InP buried layer 28 exposed on both sides of the contact layer 32, the cap layer 32, the n type InP buried layer 30 and the p type InP buried layer 29 formed in the prescribed width, on the side surfaces of the contact layer 32 and the cap layer 31 and on the contact layer 32. Thus, the entire upper and side surfaces of the device are covered with the protection film 34 of silicon oxide film.

An electrode window 36 is formed in the protection film 34 formed on the contact layer 32, arriving at the contact layer 32. On the contact layer 32 exposed in the electrode window 36 and on the protection film 34, a p type electrode 38 for injecting current into the MQW active layer 20 is formed, electrically connected to the MQW active layer 20 via the contact layer 32, the cap layer 31 and the clad layer 22.

An electrode window 40 is formed in the protection film 34 formed on the n type InP buried layer 28, arriving at the n type InP buried layer 28. On the n type InP buried layer 28 exposed in the electrode window 40 and on the protection film 34, an n type electrode 42 of the grounding potential is formed, electrically connected to the intermediate layer 18 via the n type InP buried layer 28.

On the underside of the semiconductor substrate 10, a p type electrode 44 for injecting current into the MQW wavelength control layer 16 is formed, electrically connected to the MQW wavelength control layer 16 via the semiconductor substrate 10, the diffraction grating layer 12 and the spacer layer 14.

Thus, the photosemiconductor device according to the present embodiment is constituted.

The photosemiconductor device according to the present embodiment is characterized mainly in that the effective forbidden bandwidth of the MQW wavelength control layer 16 is made larger by a value in the range of above 40 meV including 40 meV and below 60 meV excluding 60 meV than an energy of light to be wavelength controlled by the MQW wavelength control layer 16.

The effective forbidden bandwidth of the MQW wavelength control layer 16 is thus set, whereby the MQW wavelength control layer 16 can have small fundamental absorption with respect to the light-to-be-controlled generated in the MQW active layer 20 and large refractive index change. Accordingly, the variable width of the oscillation wavelength of the TTG-DFB-LD can be made large without the increase of the oscillation threshold and the decrease of the output power of the laser beams.

The wavelength variation characteristics of the photosemiconductor device according to the present embodiment were computed. In the computation, the oscillation wavelength of the TTG-DFB-LD was a 1.55 μm-band, and the effective forbidden bandwidth of the wavelength control layer was 1.47 μm, i.e., the effective forbidden bandwidth is larger by 43.5 meV than the energy of a 1.55 μm laser beam. FIG. 4 is a graph of the computation result based on the experimental results. On the horizontal axis, the widths Δλ which have changed the oscillation wavelength are taken, and the output powers of the laser beams are taken on the vertical axis. In FIG. 4, the computation result of an Example of the present invention in which the effective forbidden bandwidth of the wavelength control layer was 1.47 μm is indicated by the o-marked plots. The wavelength variation characteristics were computed also in a Control in which the effective forbidden bandwidth of the wavelength control layer was 1.40 μm. In FIG. 4, the computation result of the Control, in which the effective forbidden bandwidth of the wavelength control layer was 1.40 μm, are indicated by the ▪-marked plots.

As evident in the graph of FIG. 4, it is found that the present invention realized a 7 nm-wavelength variation width. However, when the effective forbidden bandwidth of the wavelength control layer was 1.4 μm, only a 5 nm-wavelength variation width was obtained. In comparison with the output powers of both laser beams with each other, it can be said that the application of the present invention made substantially no decrease of the output power of the laser beam.

Next, the operation of the photosemiconductor device according to the present embodiment will be explained with reference to FIGS. 3A and 3B.

First, a prescribed voltage is applied between the p type electrode 38 and the n type electrode 42 to inject current from the p type electrode 38. The current injected from the p type electrode 38 is injected into the MQW active layer 20 via the contact layer 32, the cap layer 31 and the clad layer 22 and is led out from the n type electrode 42 via the intermediate layer 18, the n type InP buried layer 28. Current of above an oscillation threshold including the oscillation threshold is injected into the MQW active layer 20 to thereby generate light in the MQW active layer 20, and the light generated in the MQW active layer 20 is oscillated in the DFB mode by the diffraction grating formed in the diffraction grating layer 12.

Concurrently a prescribed voltage is applied between the p type electrode 44 and the n type electrode 42 to inject current from the p type electrode 44. The current injected from the p type electrode 44 is injected into the MQW wavelength control layer 16 via the semiconductor substrate 10, the diffraction grating layer 12 and the spacer layer 14 and is led out from the n type electrode 42 via the intermediate layer 18 and the n type InP buried layer 28. Current is injected into the MQW wavelength control layer 16 to thereby change a refractive index of the MQW wavelength control layer 16 by the plasma effect, and a DFB oscillation wavelength of the oscillation light in the optical waveguide structure including the MQW wavelength control layer 16 is changed. Accordingly, the DFB oscillation wavelength can be controlled by the current injected into the MQW wavelength control layer 16.

In the photosemiconductor device according to the present embodiment, the effective forbidden bandwidth of the MQW wavelength control layer 16 is larger by a value in the range of above 40 meV including 40 meV and below 60 meV excluding 60 meV than the energy of light generated in the MQW active layer 20. Thus, the MQW wavelength control layer 16 has small fundamental absorption with respect to the light generated in the MQW active layer 20 and to be wavelength controlled by the MQW wavelength control layer 16 and has large refractive index change. Thus, the variable width of the oscillation wavelength can be increased without increasing the oscillation threshold and decreasing the output power of the laser beams.

Next, the method for fabricating the photosemiconductor device according to the present embodiment will be explained with reference to FIGS. 5A-5C to 9A-9C.

First, on the p type InP semiconductor substrate 10, a p type InGaAsP layer of, e.g., a 0.07 μm-thickness and a 1.2 μm-λ_{PL} (PL (PhotoLuminescence) peak wavelength) is formed by, e.g., MOCVD (Metal Organic Chemical Vapor Deposition). Then, a diffraction grating of, e.g., a 240 nm-period is formed by, e.g., EB (Electron Beam) exposure or others in the region of the p type InGaAsP layer, where the mesa stripe is to be formed. Thus, the diffraction grating layer 12 is formed.

Then, the p type InP spacer layer 14 of, e.g., a 0.1 μm-thickness is formed on the diffraction grating layer 12 by, e.g., MOCVD.

Next, the InGaAsP MQW wavelength control layer 16 of, e.g., a 1.47 μm-λ_{PL} is formed on the spacer layer 14 by, e.g., MOCVD. The MQW wavelength layer 16 is formed by alternately laying an InGaAsP barrier layer of, e.g., a 10 nm-thickness and an InGaAsP well layer of, e.g., a 3 nm-thickness 15 times, for example. The effective forbidden bandwidth of the MQW wavelength control layer 16 can be set larger by a value in the range of above 40 meV including 40 meV and below 60 meV excluding 60 meV than the energy of light generated in the MQW active layer 20 by current injection by suitably setting the material compositions, etc., of the semiconductor layers of the MQW wavelength control layer 16.

Then, the n type InP intermediate layer 18 of, e.g., a 0.2 μm-thickness is formed on the MQW wavelength control layer 16 by, e.g., MOCVCD.

Then, on the intermediate layer 18, the MQW active layer 20 of, e.g., a 1.55 μm-λ_{PL} is formed by, e.g., MOCVD. The MQW active layer is formed by alternately laying an InGaAsP barrier layer of, e.g., a 10 nm-thickness and an InGaAsP well layer of, e.g., a 5 nm-thickness 7 times, for example.

Then, on the MQW active layer 20, an InGaAsP SCH layer (not shown) of, e.g., a 0.02 μm-thickness and a 1.15 μm-λ_{PL} is formed by, e.g., MOCVD.

Next, on the SCH layer, the p type InP clad layer 22 of, e.g., a 0.2 μm-thickness is formed by, e.g., MOCVD (FIG. 5A).

Then, a silicon oxide film 46 is deposited on the clad layer 22 by, e.g., CVD.

Next, the silicon oxide film 46 is patterned into a 1.3 μm-width stripe by photolithography, and wet or dry etching. The silicon oxide film 46 is thus left selectively in the region for the mesa stripe to be formed in (FIG. 5B).

Then, with the silicon oxide film 46 as the mask, the clad layer 22, the SCH layer, the MQW active layer 20, the intermediate layer 18, the MQW wavelength control layer 16, the spacer layer 14, the diffraction grating 12 and an upper part of the semiconductor substrate 10 are anisotropically etched into, e.g., a 2.5 μm-depth to thereby form the mesa stripe of, e.g., a 1.3 μm-width (FIG. 5C).

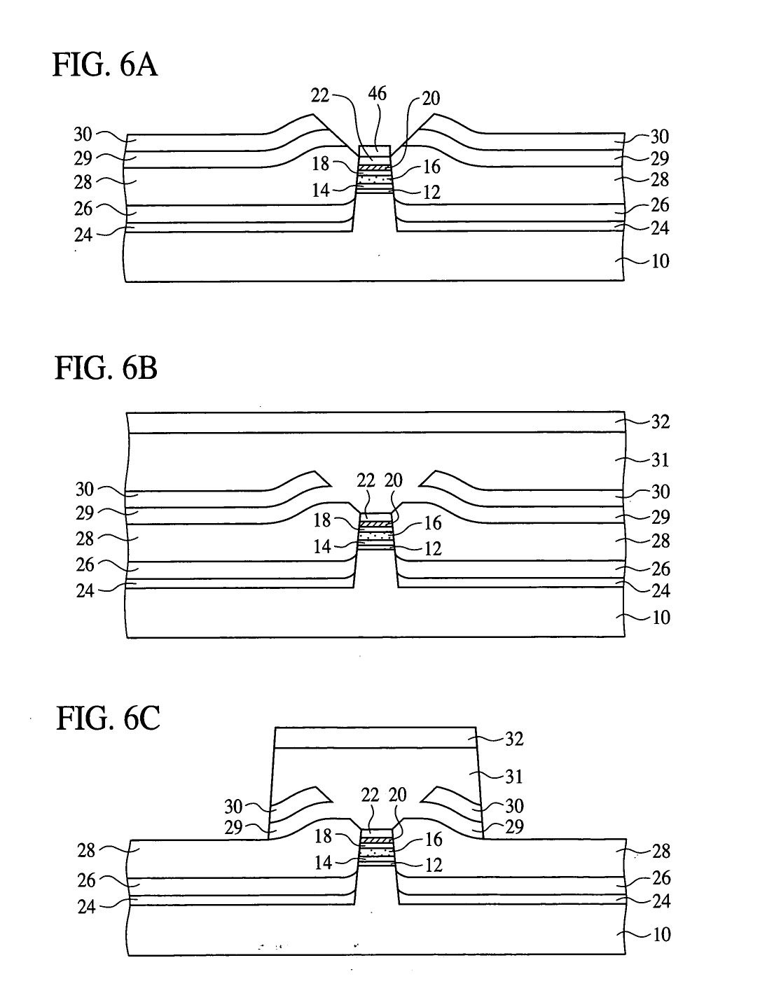

Then, with the silicon oxide film 46 as the selective growth mask, on the semiconductor substrate 10 exposed on both sides of the mesa stripe, the n type InP buried layer 24 of, e.g., a 0.5 μm-thickness, the p type InP buried layer 26 of, e. g., a 1.0 μm-thickness, the n type InP buried layer 28 of, e.g., a 1.0 μm-thickness, the p type InP buried layer 29 of, e.g., a 0.8 μm-thickness and the n type InP buried layer 30 of, e.g., a 0.3 μm-thickness are selectively grown the latter on the former (FIG. 6A). The mesa stripe is thus buried in the n type InP buried layer 24, the p type InP buried layer 26, the n type InP buried layer 28, the p type InP buried layer 29 and the n type InP buried layer 30.

The silicon oxide film 46 used as the selective growth mask is removed after the n type InP buried layer 24, the p type InP buried layer 26, the n type InP buried layer 28, the p type InP buried layer 29 and the n type InP buried layer 30 have been grown.

Then, on the mesa stripe and the n type InP buried layer 30, the p type InP cap layer 31 of, e.g., a 2.5 μm-thickness is formed by, e.g., MOCVD. The layer structure formed on the semiconductor substrate 10 is thus planarized.

Then, on the cap layer 31, the p type InGaAs contact layer 32 of, e.g., a 0.5 μm-thickness is formed by, e.g., MOCVD (FIG. 6B.)

Then, with the position of the mesa stripe as the center, the contact layer 32, the cap layer 31, the n type InP buried layer 30 and the p type InP buried layer 29 are etched into a prescribed width to thereby expose the n type InP buried layer 28 (FIG. 6C).

Then, on the entire surface of the device structure thus formed, the protection film 34 of a silicon oxide film of, e.g., a 0.55 μm-thickness is formed by, e.g., CVD (FIG. 6C).

Then, the respective electrodes of the TTG-DFB-LD are formed by the electrode forming process which will be described later.

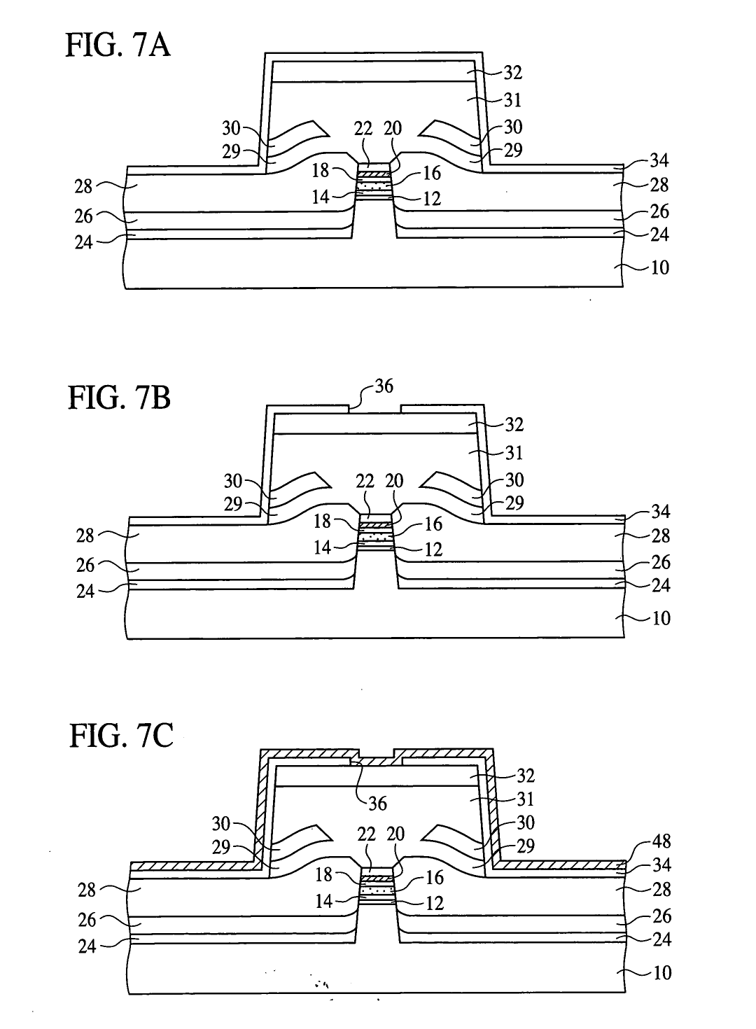

The electrode window 36 is formed by etching in the protection film 34 on the contact layer 32 down to the contact layer 32 (FIG. 7B).

Next, a Ti/Pt film 48 of, e.g., a 0.2 μm/0.25 μm is formed on the entire surface by, e.g., vapor deposition (FIG. 7C).

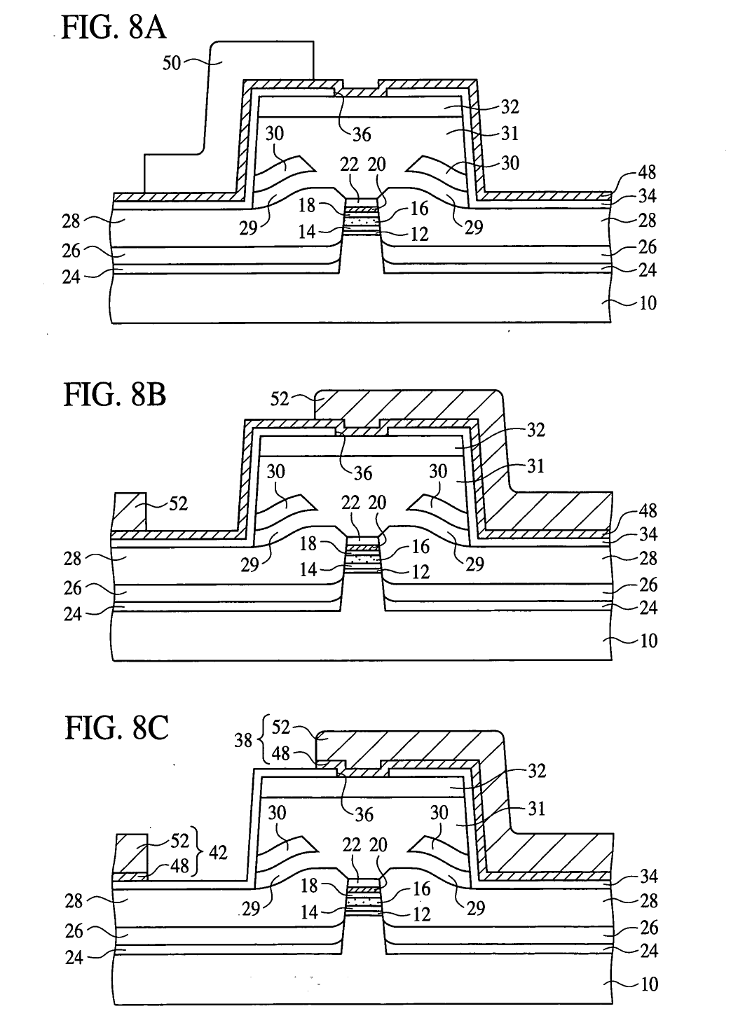

On the Ti/Pt film 48, a resist film 50 for exposing the region for the p type electrode to be formed in, which includes the electrode window 36 and the region for the n type electrode to be formed in and covering the rest region is formed (FIG. 8A).

Next, by plating with the Ti/Pt film 48 as the electrode, an Au film 52 of, e.g., a 2.0 μm-thickness is formed. At this time, the Au is not plated in the region where the resist film 50 is formed and is formed selectively in the region where the p type electrode to be formed in, which includes the electrode window 36 and the region where the n type electrode is to be formed in. After the plating is completed, the resist film 50 is removed (FIG. 8B).

Then, with the Au film 52 as the mask, the Ti/Pt film 48 is etched. The p type electrode 38 of the Ti/Pt film 48 and the Au film 52 laid the latter on the former is thus formed on the protection film 34, electrically connected to the contact layer 32 via the electrode window 36. The n type electrode 42 of the Ti/Pt film 48 and the Au film 52 latter on the former is also formed. At this time, the n type electrode 42 has not yet been connected to the n type InP buried layer 28 (FIG. 8C).

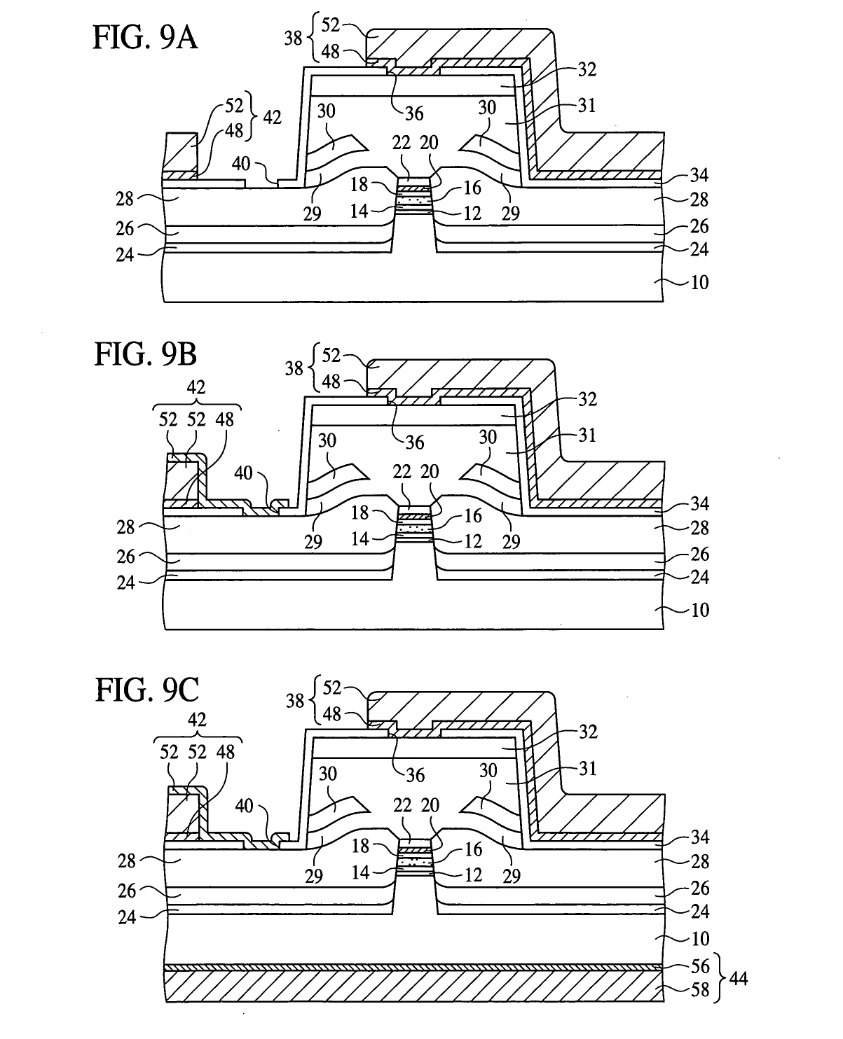

Then, the electrode window 40 is formed by etching in the protection film 34 on the n type InP buried layer 28 down to the n type InP buried layer 28 (FIG. 9A).

Then, by, e.g., vapor deposition using a resist film as the mask, an AuGe/Au film 54 of, e.g., a 0.55 μm/0.25 μm-thickness is formed. Thus, the AuGe/Au film 54 is formed, interconnecting the n type electrode 42 and the n type InP buried layer 28 exposed in the electrode window 40 (FIG. 9B).

Then, the underside of the semiconductor substrate 10 is polished to thereby reduce the thickness of the semiconductor substrate 10 to, e.g., 150 μm.

Next, an Au/Zn/Au film 56 of, e.g., a 0.015 μm/0.018 μm/0.167 μm thickness is formed on the underside of the semiconductor substrate 10 by, e.g., vapor deposition.

Next, By plating with the Au/Zn/Au film 56 as the electrode, an Au film 58 of, e.g., a 3.0 μm-thickness is formed. Thus, the p type electrode 44 of the Au/Zn/Au film 56 and the Au film 58 laid the latter on the former is formed on the underside of the semiconductor substrate 10 (FIG. 9C).

Thus, the photosemiconductor device according to the present embodiment is fabricated.

Next, the result of evaluating the photosemiconductor device according to the present embodiment will be explained with reference to FIG. 10.

On the TTG-DFB-LD fabricated by the method for fabricating the photosemiconductor device according to the present embodiment illustrated in FIGS. 5A-5C to 9A-9C, wavelength spectra of the laser beams were measured with the oscillation wavelength varied. FIG. 10 is a graph of the measured result, and the oscillation wavelengths were taken on the horizontal axis, and the output powers of the laser beams were taken on the vertical axis.

Based on the graph of FIG. 10, it is found that the variable width of the oscillation wavelength which is as wide as 7.06 nm is obtained without decreasing the output power of the laser beams.

As described above, according to the present embodiment, the effective forbidden bandwidth of the MQW wavelength control layer 16 is set larger by a value in the range of above 40 meV including 40 meV and below 60 meV excluding 60 meV than an energy of the light generated in the MQW active layer 20 to be wavelength controlled by the MQW wavelength control layer 16, whereby the fundamental absorption of the MQW wavelength control layer 16 can be made small, and the refractive index change of the MQW wavelength control layer 16 by the current injection can be made large. Accordingly, the variable width of the oscillation wavelength of the TTG-DFB-LD can be made large without increasing the oscillation threshold and decreasing the output power of the laser beams.

### Modified Embodiments

The present invention is not limited to the above-described embodiment and can cover other various modifications.

For example, in the present embodiment, the photosemiconductor device using a p type semiconductor substrate is used. However, the present invention is similarly applicable to photosemiconductor devices using an n type semiconductor substrate. In this case, the conduction types of the respective layers of the above-described embodiment are exchanged.

The photosemiconductor device is not essentially formed of the material groups described in the above-described embodiment but may be formed of other material groups. The sizes, such as the film thicknesses, etc., of the respective layers, the impurity concentrations, etc. may be suitably design changed as required. In the above-described embodiment, the TTG-DFB-LD which uses InP/InGaAsP group materials and oscillates in a 1.55 μm-band is explained. However, the present invention is applicable to TTG-DFB-LDs which use other material groups and oscillate at a wavelength band different from the 1.55 μm-band, whereby the effective forbidden bandwidths of the wavelength control layers are set as described above, and the fundamental absorption of the wavelength control layers can be made small while the refractive index change of the wavelength control layers by the current injection can be made large. Thus, TTG-DFB-LDs which oscillate at wavelength bands different from the 1.55 μm-band can made the variable width of the oscillation wavelength large without the increase of the oscillation threshold and the decrease of the output power of the laser beams. Specifically, the present invention is applicable to, e.g., the TTG-DFB-LD which uses InP/InGaAsP group materials and oscillates at a 1.3 μm-band.

In the above-described embodiment, the semiconductor layers, such as the InP layer, the InGaAs layer and the InGaAsP layer, are formed by MOCVD. However, these layers are not formed essentially by MOCVD and may be formed by, e.g., MBE (Molecular Beam Epitaxy).

In the above-described embodiment, the MQW active layer 20 is formed on the MQW wavelength control layer 16 via the intermediate layer 18. The position of the MQW wavelength control layer 16 and the position of the MQW active layer 20 may be exchanged with each other. That is, the MQW wavelength control layer 16 may be formed on the MQW active layer 20 via the intermediate layer 18. In this structure, current is injected into the MQW active layer 20 from the p type electrode 44 formed on the underside of the semiconductor substrate 10, and current is injected into the MQW wavelength control layer 16 from the p type electrode 38 formed on the contact layer 32.

In the above-described embodiment the MQW wavelength control layer 16 has the multiple quantum well structure. However, in place of the MQW wavelength control layer 16, a wavelength control layer having a single quantum well structure or a wavelength control layer of a bulk semiconductor layer may be used.

In the above-described embodiment, the present invention is applied to the TTG-DFB-LD. However, the present invention is applicable to various photosemiconductor devices including optical waveguides formed of refractive index control layers whose refractive indexes are changed by the current injection. In these cases as well as the above-described embodiment, as in the above-described embodiment, the effective forbidden bandwidths of the refractive index control layers are set larger by a value in the range of above 40 meV including 40 meV and below 60 meV excluding 60 meV than an energy of the light-to-be-controlled which propagates through the optical waveguides including the refractive index control layers and whose wavelength, etc. are to be controlled by the refractive index control layer, whereby the refractive index control layers having small fundamental absorption with respect to the light-to-be-controlled and large refractive index changes by the current injection can be realized. Such refractive index control layers make it possible to realize the photosemiconductor devices having excellent device characteristics, such as variable wavelength lasers, variable wavelength filters, etc. having wide variable wavelength widths.

1. A photosemiconductor device comprising an optical waveguide including a refractive index control layer whose refractive index varies by current injection,
an effective forbidden bandwidth of the refractive index control layer being larger by a value of above 40 meV including 40 meV and below 60 meV excluding 60 meV than an energy of light propagating through the optical waveguide.

2. A photosemiconductor device according to claim 1, wherein
the optical waveguide further comprises:
an active layer for generating by current injection the light propagating through the optical waveguide; and
a light oscillation part for oscillating the light propagating through the optical waveguide.

3. A phtosemiconductor device according to claim 2, wherein
the optical waveguide further includes an intermediate layer formed between the refractive index control layer and the active layer.

4. A photosemiconductor device according to claim 3, wherein
the optical waveguide is formed on a semiconductor substrate, and
the active layer is laid on the refractive index control layer with the intermediate layer formed therebetween.

5. A photosemiconductor device according to claim 3, wherein
the optical waveguide is formed on a semiconductor substrate, and
the refractive index control layer is laid on the active layer with the intermediate layer formed therebetween.

6. A photosemiconductor device according to claim 3, wherein
the light oscillation part includes a diffraction grating formed near the refractive index control layer and the active layer.

7. A photosemiconductor device according to claim 4, wherein
the light oscillation part includes a diffraction grating formed near the refractive index control layer and the active layer.

8. A photosemiconductor device according to claim 5, wherein
the light oscillation part includes a diffraction grating formed near the refractive index control layer and the active layer.

9. A photosemiconductor device according to claim 2, wherein
the light propagating through the optical waveguide has an oscillation wavelength of a 1.55 μm-band.

10. A photosemiconductor device according to claim 3, wherein
the light propagating through the optical waveguide has an oscillation wavelength of a 1.55 μm-band.

11. A photosemiconductor device according to claim 4, wherein
the light propagating through the optical waveguide a has an oscillation wavelength of a 1.55 μm-band.

12. A photosemiconductor device according to claim 5, wherein
the light propagating through the optical waveguide has an oscillation wavelength of a 1.55 μm-band.

13. A photosemiconductor device according to claim 1, wherein
the optical waveguide is formed of an InP/InGaAsP-based material.

14. A photosemiconductor device according to claim 2, wherein
the optical waveguide is formed of an InP/InGaAsP-based material.

15. A photosemiconductor device according to claim 3, wherein
the optical waveguide is formed of an InP/InGaAsP-based material.

16. A photosemiconducdtor device according to claim 1, wherein
the refractive index control layer has a quantum well structure.

17. A photosemiconducdtor device according to claim 2, wherein
the refractive index control layer has a quantum well structure.

18. A photosemiconducdtor device according to claim 3, wherein
the refractive index control layer has a quantum well structure.

19. A wavelength control method for light propagating a optical waveguide comprising a refractive index control layer having an effective forbidden bandwidth which is larger by a value of above 40 meV including 40 meV and below 60 meV excluding 60 meV than the light propagating through the optical waveguide,
the method injecting current into the refractive index control layer to control a wavelength of the light propagating through the optical waveguide.
